(19) United States
(12) Patent Application Publication
(10) Pub. No.: US 2008/0237872 A1
(43) Pub. Date: Oct. 2, 2008

(54) Semiconductor Device and Method For Manufacturing Same

(76) Inventor: Kenichi Nagayama, Saitama (JP)

Correspondence Address: DRINKER BIDDLE & REATH (DC), 1500 K STREET, N.W., SUITE 1100, WASHINGTON, DC, 20005-1209, US

(21) Appl. No.: 10/586,584

(22) PCT Filed: Jan. 19, 2005
(86) PCT No.: PCT/JP05/00934

§ 371 Date: Feb. 28, 2008

(30) Foreign Application Priority Data
Jan. 21, 2004 (JP) 2004-012967

(51) Int. Cl. H01L 23/52; H01L 21/31

(52) U.S. Cl. 257/773; 438/778; 257/E23.141

(57) ABSTRACT

Disclosed is a semiconductor apparatus having a sealing structure that allows high-precision detection of defects occurring in a protective film, and a method of manufacturing the same. A semiconductor apparatus 1 includes a substrate 10, a semiconductor device 14 formed on the substrate 10, and a protective film 17 for sealing the semiconductor device 14. The semiconductor apparatus 1 further includes a first conductive layer 16 in contact with a back surface of the protective film 17, and a second conductive layer 18 in contact with a front surface of the protective film 17.

### TECHNICAL FIELD

The present invention relates to a structure for sealing a semiconductor device such as an organic EL (ElectroLuminescent) device, a light-emitting diode, or a capacitive device.

### BACKGROUND ART

Organic EL panels are equipped with organic EL devices which have light-emitting layers mainly consisting of organic materials. Since an organic EL device may be degraded by exposure to moisture, oxygen, and the like, a protective film (passivation film) that covers and seals the entire organic EL device is formed to shield it from outside air. For improving sealing capability, the protective film typically includes a dense film having high blocking capability against impurity penetration.

If the protective film has defects such as cracks or pinholes, impurities such as moisture and oxygen that penetrate through the defects promote oxidation and the like of the device materials, thereby degrading the organic EL device. This kind of degradation can lead to the occurrence and expansion of dark spots (non-luminous points) in a light-emitting surface, a shorter device lifetime, and a drop in yield. Thus, when the defects occur, prevention of the occurrence of the defects and repair of the defects are significant issues. Sealing techniques for solving such issues are disclosed, for example, in patent document 1 (Japanese Patent Application Publication (KOKAI) No. 2002-134270), patent document 2 (Japanese Patent Application Publication (KOKAI) No. 2002-164164), patent document 3 (Japanese Patent Application Publication (KOKAI) No. Hei 6-96858), patent document 4 (Japanese Patent Application Publication (KOKAI) No. Hei 10-312883), patent document 5 (Japanese Patent Application Publication (KOKAI) No. 2002-260846), and patent document 6 (Japanese Patent Application Publication (KOKAI) No. 2002-329720).

In addition, techniques for detecting defects of the protective film that occurs in the manufacturing processes are also important in improving yield and in repairing defects. It is possible to detect defects occurring in the protective film by visual inspection or image processing. It is difficult, however, for the visual inspection or the image processing to accurately detect an unexpected defect or the defect that does not appear in the surface of the protective film. Therefore, the detection accuracy is limited due to the difficulty.

In view of the foregoing, it is a main object of the present invention to provide a semiconductor apparatus having a sealing structure that allows high-precision detection of defects occurring in a protective film for sealing semiconductor devices such as an organic EL device, and a method of manufacturing the same.

### DISCLOSURE OF THE INVENTION

To achieve the above object, a semiconductor apparatus according to the present invention comprises a substrate, a semiconductor device formed on the substrate, and a protective film for sealing the semiconductor device. The semiconductor apparatus further comprises a first conductive layer in contact with a back surface or backside of the protective film, and a second conductive layer in contact with a front surface or frontside of the protective film.

A method of manufacturing a semiconductor apparatus according to the present invention detects a defect within a protective film that seals a semiconductor device formed on a substrate. The method comprises the steps of: (a) forming a first conductive layer; (b) forming a protective film for covering the semiconductor device on the first conductive layer; (c) forming a second conductive layer on the protective film; and (d) measuring electrical conduction between the first conductive layer and the second conductive layer, and detecting a defect within the protective film based on the measurement result.

### BRIEF DESCRIPTION OF THE DRAWINGS

FIG. 1 is a diagram schematically showing a cross section of an organic EL panel according to a first embodiment of the present invention;

FIG. 2 is a sectional view schematically showing an example of an organic function layer constituting an organic EL device;

FIG. 3 is a diagram schematically showing a cross section of the organic EL panel according to the first embodiment;

FIG. 4 is a diagram schematically showing a cross section of the organic EL panel in which a defect of a protective film is repaired;

FIG. 5 is a plan view schematically showing an organic EL panel according to a second embodiment of the present invention;

FIG. 6 is a plan view schematically showing the organic EL panel of the second embodiment;

FIGS. 7A and 7B are graphical representations for explaining defect detection processing of the second embodiment;

FIG. 8 is a plan view schematically showing an organic EL panel according to a third embodiment of the present invention;

FIG. 9 is a plan view schematically showing the organic EL panel of the third embodiment;

FIG. 10 is a diagram schematically showing a cross section of an organic EL panel according to a fourth embodiment of the present invention;

FIG. 11 is a plan view schematically showing the organic EL panel of the fourth embodiment; and

FIG. 12 is a diagram schematically showing a cross section of the organic EL panel in which a defect of a protective film is repaired.

### MODE FOR CARRYING OUT THE INVENTION

Hereinafter, various embodiments according to the prevent invention will be described.

### 1. First Embodiment

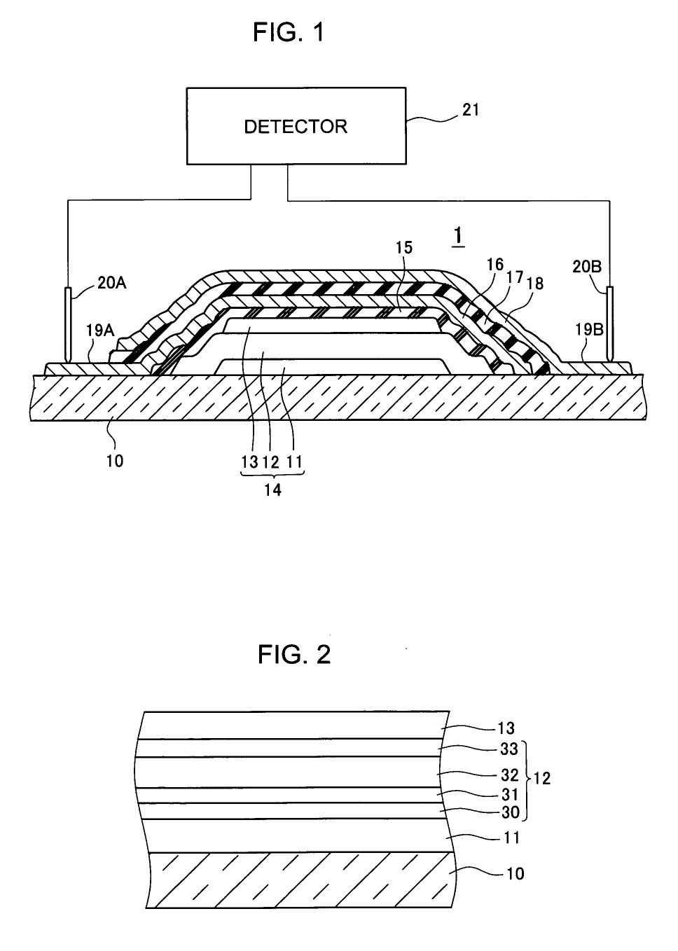

FIG. 1 is a diagram schematically showing a cross section of an organic EL panel (semiconductor apparatus) 1 according to a first embodiment of the present invention. This organic EL panel 1 comprises an insulating substrate 10, and an organic EL device (semiconductor device) 14 consisting of a first electrode layer 11, an organic function layer 12, and a second electrode layer 13 which are formed on this insulating substrate 10. The insulating substrate 10 may be a glass substrate or a flexible plastic substrate with a base of polycarbonate or the like as an example.

The organic EL panel 1 also has an insulating film 15 of electrical insulation, a first conductive layer 16, a protective film (passivation film) 17, and a second conductive layer 18 which are deposited in this order on the organic EL device 14. The first conductive layer 16 and the second conductive layer 18 are formed in contact with both the backside (inner side) of the protective film 17 and the frontside (outer side) of the protective film 17.

The protective film 17 is made of one or more layers of films for preventing impurities such as moisture and oxygen from penetrating into the organic EL device 14. The protective film 17 is sandwiched between the first conductive layer 16 and the second conductive layer 18, and is formed so as to establish electric insulation between the first conductive layer 16 and the second conductive layer 18. Examples of constituent materials of the protective film 17 can be metal oxides including silicon oxide (SiO₂), metal nitrides including silicon nitride, metal oxynitrides including silicon oxynitride (SiON), and organic insulating materials including polyimide resins. These film materials can be deposited to form the protective film 17 by such processes as vacuum deposition, spin coating, sputtering, plasma CVD (Chemical Vapor Deposition), laser CVD, thermal CVD, and ion plating.

In particular, ion plating or CVD is preferably used in order to improve adhesiveness to the first conductive layer 16 and to form the protective film 17 with fewer pinholes. To form a dense uniform film having less pinholes and a constant film thickness, it is preferable to deposit the protective film 17 by CVD using polyparaxylene resins such as polyparaxylylene, polymonochloroparaxylylene, polydichloroparaxylylene, and polymonobromparaxylylene.

Furthermore, in order to improve moisture-proof characteristics, the protective film 17 preferably includes a moisture absorbing film of alkali metal oxides such as calcium oxide or barium oxide, and organics having isocyanate groups.

Constituent materials of the first conductive layer 16 and the second conductive layer 18 can be: one or an alloy of two or more selected from such metal materials as aluminum (Al), silver (Ag), copper (Cu), gold (Au), platinum (Pt), palladium (Pd), chromium (Cr), molybdenum (Mo), titanium (Ti), and nickel (Ni); transparent conductive materials such as ITO (Indium Tin Oxide), IZO (Indium Zinc Oxide), and tin oxide; or conductive polymeric materials such as polythiophene and polyaniline. In particular, in order to achieve high-precision defect detection on the protective film 17 that is described later, metal materials or transparent conductive materials having high electrical conductivity are preferably selected.

As shown in FIG. 1, the first conductive layer 16 exists over a peripheral part of the insulating substrate 10 outside the area in which the organic EL device 14 is formed. The first conductive layer 16 on this peripheral part is continuous with and electrically connected with a first electrode terminal 19A. This first electrode terminal 19A has a surface area such that a metal probe 20A intended for defect detection can make contact with the terminal 19A. The second conductive layer 18 also exists over a peripheral part of the insulating substrate 10 outside the area in which the organic EL device 14 is formed. The second conductive layer 18 on this peripheral part is continuous with and electrically connected with a second electrode terminal 19B. This electrode terminal 19B has a surface area such that a metal probe 20B intended for defect detection can make contact with the terminal 19B. The first and second probes 20A and 20B are connected to a detector 21 for performing defect detection processing. The defect detection processing will be described later.

The insulating film 15 can be a film for electrically insulating the organic EL device 14 from the first conductive layer 16. Constituent materials and processes for forming the insulating film 15 are not limited in particular. In the process of forming the insulating film 15, however, it is preferable to select a film material that allows minimize damage to an underlying device structure. The insulating film 15 can be formed by a process such as sputtering, vacuum deposition, CVD, spin coating, or screen printing.

The electrode patterns of the first electrode layer 11 and the second electrode layer 13 constituting the organic EL device 14 are not explicitly shown in the figure. The first electrode layer 11 and the second electrode layer 13 may be patterned into stripes in directions orthogonal to each other. In order to inject holes into the organic function layer 12, the first electrode layer 11 is preferably made of an anode material having high work function. For example, the first electrode layer 11 can be formed by depositing an anode material of a conductive metal oxide such as ITO (Indium Tin Oxide), IZO (Indium Zinc Oxide), and tin oxide on the insulating substrate 10 by vacuum deposition, sputtering, ion plating, or vapor phase epitaxy, followed by patterning using a resist as a mask. Moreover, in order to inject electrons into the organic function layer 12, the second electrode layer 13 is preferably made of a cathode material that has a low work function and is chemically relatively stable. For example, the second electrode layer 13 can be formed by depositing a cathode material such as an Mg—Ag alloy, magnesium, aluminum, and an aluminum alloy on the organic function layer 12 by vacuum deposition or the like, followed by patterning.

It should be appreciated that in the present embodiment, the first electrode layer 11 is described as an anode for injecting holes into the organic function layer 12, and the second electrode layer 13 as a cathode for injecting electrons into the organic function layer 12. Alternatively, the first electrode layer 11 may be a cathode and the second electrode layer 13 an anode.

Next, FIG. 2 is a sectional diagram schematically showing an example of the organic function layer 12. Referring to FIG. 2, the organic function layer 12 is formed by depositing a hole injection layer 30, a hole transporting layer 31, a light-emitting layer 32, and an electron injection layer 33 in this order on the insulating substrate 10 over the first electrode layer 11. The second electrode layer 13 is formed on the electron injection layer 33. When holes are injected from the first electrode layer 11 and electrons are injected from the second electrode layer 13 by applying a voltage from an external source, the holes and electrons injected into the organic function layer 12 recombine at a predetermined probability in the light-emitting layer 32. The recombination energy is emitted through either one or both of a singlet excited state and a triplet excited state of organic molecules that constitute the light-emitting layer 32, thereby emitting light as fluorescence, phosphorescence, or both fluorescence and phosphorescence. Constituent materials of the hole injection layer 30 and the hole transporting layer 31 may be copper phthalocyanine and TPD (triphenylamine dimer), or polythiophene and polyaniline. Constituent materials of the light-emitting layer 32 may include Alq₃ (aluminum quinolinol derivative), BAlq₁ (aluminum quinolinol derivative), DPVBi (distyryl arylene derivative), EM2 (oxadiazole derivative), and BMA-nT (oligothiophene derivative; n is a positive integer). Constituent materials of the electron injection layer 33 may include Li₂O (lithium oxide).

It should be appreciated that the foregoing organic function layer 12 is a four-layered device. Alternatively, the organic function layer 12 may be a single-layered device made of the light-emitting layer 32 alone, or a triple-layered device made of the light-emitting layer 32, the hole transporting layer 31, and the hole injection layer 30.

In addition to the components shown in FIG. 1, the organic EL panel 1 may include not-shown components such as a plurality of partitions sectioning the organic EL device 14, and drive circuits that contain components such as TFTs (thin film transistors) and capacitors.

A method of manufacturing the organic EL panel 1 having the foregoing configuration will now be described schematically.

Referring to FIG. 1, the first electrode layer 11, the organic function layer 12, and the second electrode layer 13 are initially formed in this order on the insulating substrate 10, whereby the organic EL device 14 is formed in the device-forming area on the insulating substrate 10. Next, the insulating film 15 is formed on the organic EL device 14 by using an insulating material such as a metal nitride film.

Then, a metal material such as aluminum is deposited to cover the organic EL device 14 and the insulating film 15 by vapor deposition, sputtering, or the like, followed by patterning. As a result, the electrode terminal 19A and the first conductive layer 16 are formed. Subsequently, by using CVD, the protective film 17 is formed by depositing an insulating material such as silicon nitride so as to cover the first conductive layer 16. Furthermore, the second conductive layer 18 and the electrode terminal 19B are formed by depositing a metal material such as aluminum so as to cover this protective film 17 by vapor deposition, sputtering, or the like, followed by patterning.

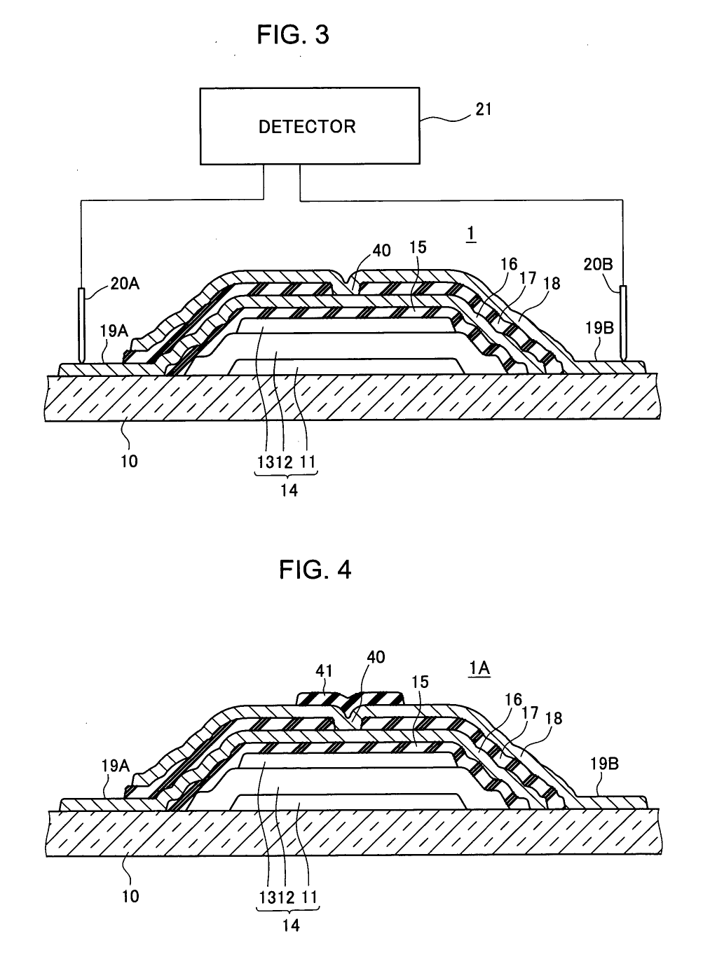

Then, defect detection processing is performed on the protective film 17. Specifically, as shown in FIG. 1, one probe 20A is in contact with the electrode terminal 19A, and the other probe 20B is in contact with the electrode terminal 19B. In this state, the detector 21 applies a potential difference between the electrode terminals 19A and 19B. The detector 21 further measures electrical conduction, for example, by measuring an electric resistance between the electrode terminals 19A and 19B, and detects a defect within the protective film 17 based on the measurement result. If the protective film 17 has any defect 40 as shown in FIG. 3, the first conductive layer 16 and the second conductive layer 18 are electrically conductive via the defect 40. On the other hand, if the protective film 17 has no defect as shown in FIG. 1, there exists little electrical conduction between the first conductive layer 16 and the second conductive layer 18, so that the electric conductivity between the two layers is low and the electric resistance between the layers is high. Thus, if the detector 21 judges that there is electrical conduction between the electrode terminals 19A and 19B, it determines that the protective film 17 has a defect. On the other hand, if the detector 21 judges that there is no electrical conduction between the electrode terminals 19A and 19B, it determines that the protective film 17 has no defect. For example, if the measured electric resistance exceeds a predetermined set value, the protective film 17 is determined to have none of the defects as a pinhole. If the measured electric resistance is lower than or equal to the set value, the protective film 17 can be determined to have a defect. The result of determination on the presence or absence of any detect is displayed on an LED indicator or the like.

Through the defect detection processing described above, it is possible to detect defects of the protective film 17 with high precision. Moreover, incorporation of the foregoing defect detection processing into the process of manufacturing the organic EL panel 1 makes it possible to find defective units at an early stage, so that the organic EL panel 1 can be provided with high reliability.

When any defect of the protective film 17 is detected in the foregoing defect detection processing, a repair process follows in which an uneven surface of the second conductive layer 18 corresponding to at least the region of and in the vicinity of the detected defect is planarized. Then, an insulating material having a high barrier property is deposited on the second conductive layer 18 corresponding to a region of and in the vicinity of the detected defect, thereby forming a repair layer (patch layer) 41 such as shown in FIG. 4. Specifically, the uneven surface corresponding to a region of and in the vicinity of the detected defect is planarized by forming a resin film of parylene or the like by a dry process such as CVD, or applying a light-curing or heat-curing resin using a wet process, followed by curing. Then, an insulating material having a high barrier property, such as silicon nitride, can be deposited on the planarized surface.

It should be appreciated that the repair layer 41 may be formed over the entire device-forming area of the organic EL panel 1. Alternatively, the repair layer 41 may be locally formed so as to only cover the surface of the second conductive layer 18 corresponding to a region of and in the vicinity of the defect. For example, in the process of film formation such as vacuum deposition and sputtering, a shielding plate having holes or nozzles may be arranged in front of the organic EL panel 1. The film material can be locally deposited on the region of and in the vicinity of the defect alone by using the shielding plate as a mask.

The foregoing repair process can provide an organic EL panel 1A in which the defect 40 of the protective film 17 is repaired as shown in FIG. 4. This makes it possible to provide the organic EL panel 1 that precludes degradation of its organic EL devices and that has a long lifetime with an improved yield.

It should be appreciated that after the formation of the repair layer 41 described above, a sealing member for sealing the entire organic EL panel 1A may be formed in order to further improve the sealing capability and reinforcement in mechanical strength. Specifically, a metal member with a drying agent may be attached to the insulating substrate 10 as a sealing member by using an ultraviolet-curable resin or other adhesive under an inert gas environment.

### 2. Second Embodiment

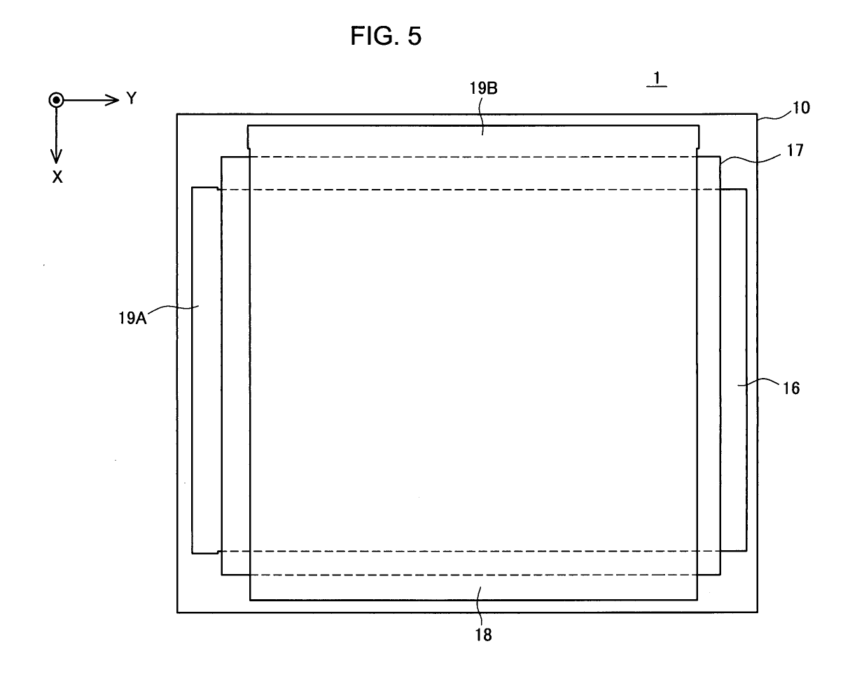

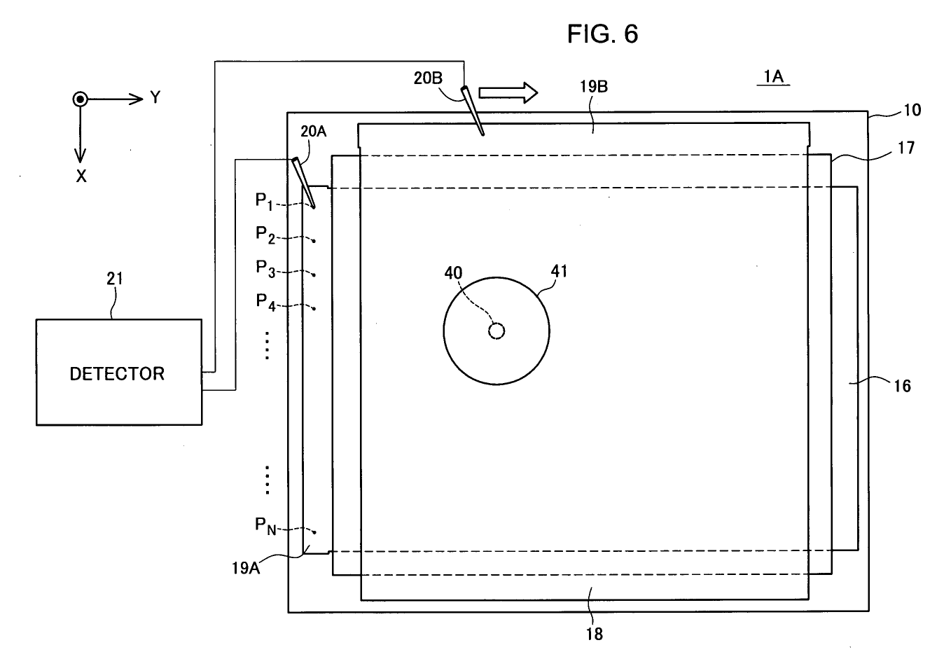

Next, description will be given of a second embodiment according to the present invention. FIG. 5 is a plan view schematically showing an organic EL panel (semiconductor apparatus) 1 of the second embodiment. In FIG. 5, components designated by the same reference numerals as those shown in FIG. 1 have the same configuration and are manufactured by the same processes as those of the components of the foregoing first embodiment. Detailed description thereof will thus be omitted.

Referring to FIG. 5, an organic EL device 14 (not shown) is formed in a device-forming area on an insulating substrate 10. A first conductive layer 16, a protective film 17, and a second conductive layer 18 are formed in this order so as to cover the entire device-forming area. One electrode terminal 19A is formed on one of peripheral parts of the insulating substrate 10 outside the device-forming area, in a band-shaped region in X-direction along the peripheral part. Another electrode terminal 19B is formed on another peripheral part of the insulating substrate 10 outside the device-forming area, in a band-shaped region in Y-direction along the peripheral part, i.e., in a direction orthogonal to the X-direction.

To measure electrical conduction between the first conductive layer 16 and the second conductive layer 18, one probe 20A is initially in contact with a measuring point P₁ on a surface of the electrode terminal 19A as shown in FIG. 6. Next, the other probe 20B is in contact with a surface of the electrode terminal 19B, and the probe 20B is scanned from one end of the electrode terminal 19B to the other in the Y-direction. During the scanning of this probe 20B, the detector 21 measures a distribution of a quantity that indicates the electrical conduction between the probes 20A and 20B (e.g., an electric resistance) with reference to the Y-direction, and records the measured distribution into an internal memory (not shown). Next, the foregoing measurement processing is repeated for a next measuring point P₂.

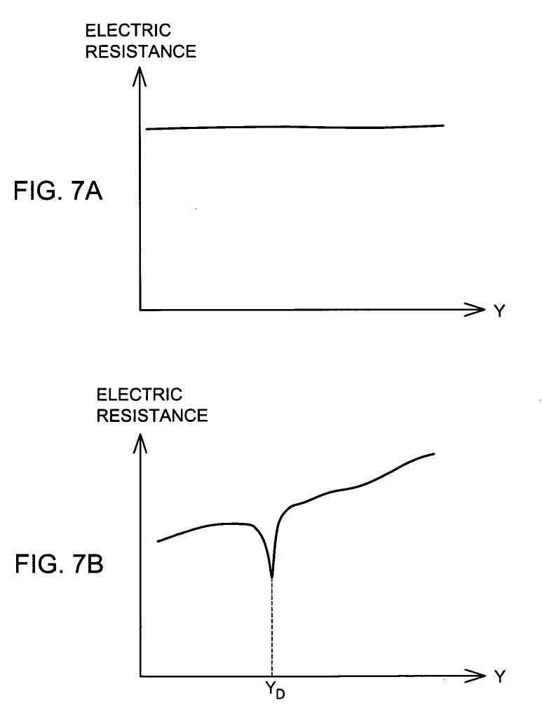

Subsequently, the measurement processing is completed for all the measuring points P₁, P₂, . . . , P_{N} (N is a positive integer of not less than 2). Then, the detector 21 reads the stored distribution of the electrical conduction from the internal memory, analyzes the read distribution, detects defects within the protective film 17, and identifies a region of the detected defect. FIGS. 7A and 7B are graphical representations each schematically showing an example of a distribution curve of the electric resistance for a certain measuring point P_{K} (K is an integer of 1 to N). If the protective film 17 has no defect for the measuring point P_{K}, the distribution of the electric resistance has substantially a constant value as shown in the graph of FIG. 7A. On the other hand, if the protective film 17 has a defect for the measuring point P_{K}, the distribution of the electric resistance peaks at a position Y_{D} corresponding to the defect as shown in the graph of FIG. 7B. By detecting an abnormality such as the peak shown in FIG. 7B from the distribution of the measured electrical conduction, the detector 21 can detect defects of the protective film 17.

Moreover, if the protective film 17 has a defect 40 as shown in FIG. 6, the distribution of the measured electrical conduction shows an abnormality such as shown in FIG. 7B corresponding to positions of the two probes 20A and 20B. The detector 21 can thus identify the region of this defect 40. Then, a repair layer 41 is locally formed on the frontside or front surface of the second conductive layer 18 corresponding to at least the region of and in the vicinity of the defect, thereby repairing the defect 40.

As described above, according to the second embodiment, it is possible to identify the region of the defect of the protective film 17. Thus, an area in which the repair layer 41 is to be formed and whether or not the repair is needed can be quickly and easily determined, depending on the regions of and the number of the defects of the protective film 17.

### 3. Third Embodiment

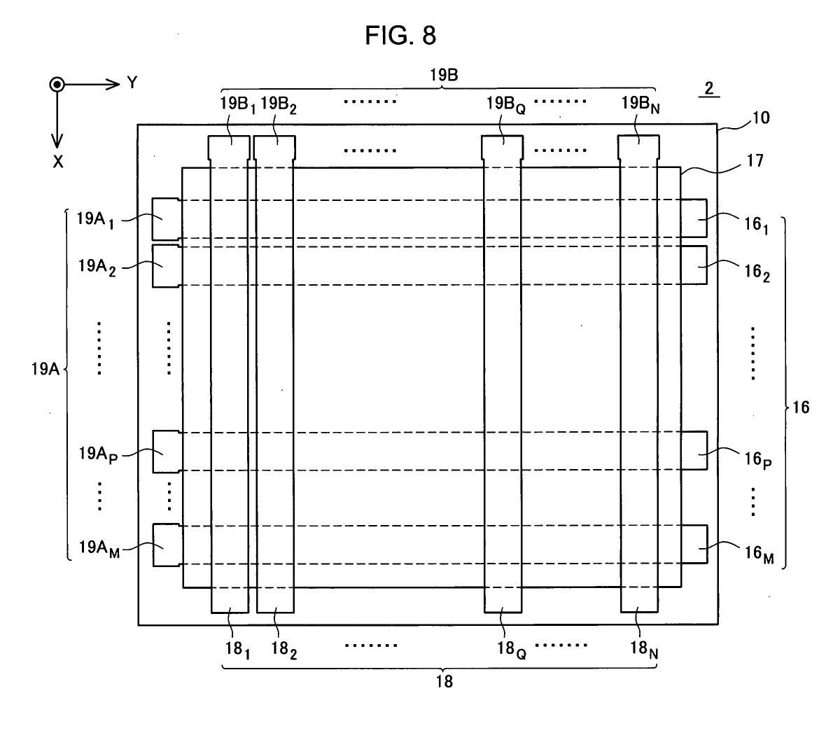

Next, description will be given of a third embodiment according to the present invention. FIG. 8 is a plan view schematically showing an organic EL panel (semiconductor apparatus) 2 of the third embodiment. In FIG. 8, components designated by the same numerals as those shown in FIG. 1 have the same configuration and are manufactured by the same processes as those of the components of the foregoing first embodiment. Detailed description thereof will thus be omitted.

Referring to FIG. 8, an organic EL device 14 (not shown) is formed in a device-forming area on an insulating substrate 10. A first conductive layer 16, a protective film 17, and a second conductive layer 18 are formed in this order so as to cover the entire device-forming area. The first conductive layer 16 and the second conductive layer 18 are patterned into stripes so as to cross each other. The first conductive layer 16 is composed of a plurality of the band-shaped conductive pieces 16₁, 16₂, . . . , 16_{M} which are arranged at predetermined intervals in X-direction along one of peripheral parts of the insulating substrate 10 and extend in Y-direction orthogonal to the X-direction. The second conductive layer 18 is composed of a plurality of the band-shaped conductive pieces 18₁, 18₂, . . . , 18_{N} which are arranged at predetermined intervals in the Y-direction along another peripheral part of the insulating substrate 10 and extend in the X-direction.

In addition, an electrode terminal 19A that is continuously connected to the first conductive layer 16 is formed on one peripheral part of the insulating substrate 10 outside the device-forming area. An electrode terminal 19B that is continuously connected to the second conductive layer 18 is formed on another peripheral part. The one electrode terminal 19A is composed of a plurality of electrode pieces 19A₁, 19A₂, . . . , 19A_{M} which are arranged in the X-direction along the one peripheral part of the insulating substrate 10. The electrode pieces 19A₁, 19A₂, . . . , 19A_{M} are continuous with the band-shaped conductive pieces 16₁, 16₂, . . . , 16_{M}, respectively. The other electrode terminal 19B is composed of a plurality of electrode pieces 19B₁, 19B₂, . . . , 19B_{N} which are arranged in the Y-direction along the other peripheral part. The electrode pieces 19B₁, 19B₂, . . . , 19B_{N} are continuous with the band-shaped conductive pieces 18₁, 18₂, . . . , 18_{N}, respectively.

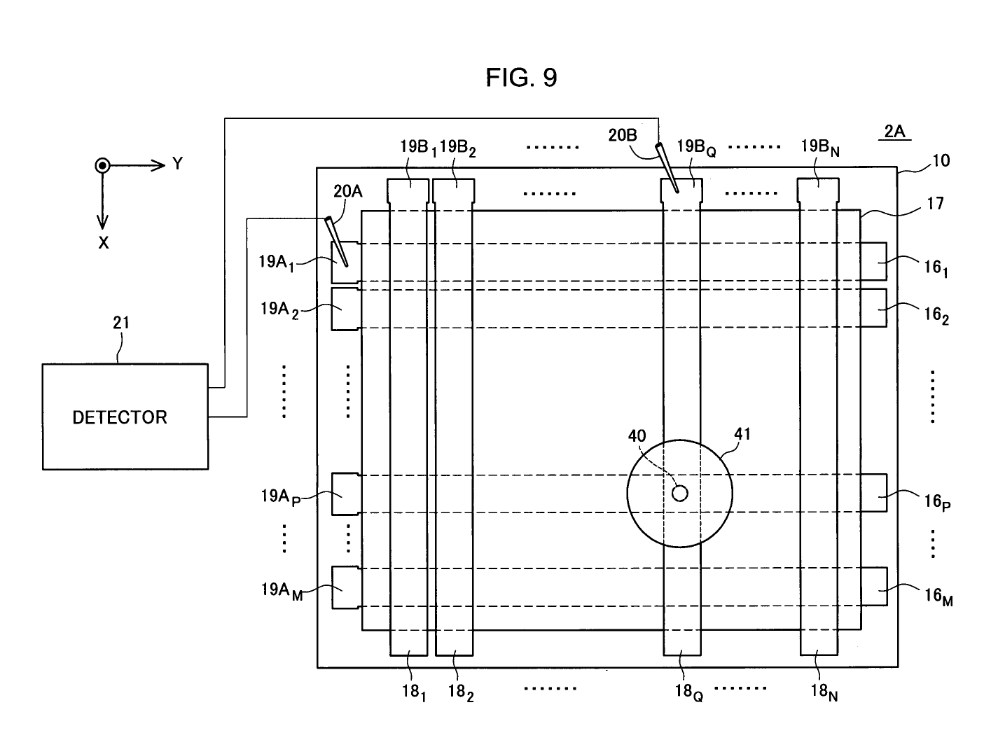

To measure electrical conduction between the first conductive layer 16 and the second conductive layer 18, one probe 20A is initially in contact with a surface of the electrode piece 19A₁ as shown in FIG. 9. Next, the other probe 20B is put in contact with the electrode piece 19B₁. The detector 21 measures a quantity that indicates the electrical conduction between the probes 20A and 20B (e.g., an electric resistance), and records the measured quantity into an internal memory (not shown) in association with the positions of the probes 20A and 20B. Next, the other probe 20B in contact with the surface of the electrode piece 19B₂ is scanned. In this state, the quantity that indicates the electrical conduction is measured, and recorded into the internal memory in association with the positions of the probes 20A and 20B. In this way, the electrical conduction is measured for all the M×N combinations of the electrode pieces 19A₁, . . . , 19A_{M} arranged in the X-direction and the electrode pieces 19B₁, . . . , 19B_{N} arrange in the Y-direction. The measurement results are stored into the internal memory.

Subsequently, the detector 21 reads the M×N measurement results stored in the internal memory, analyzes these results, detects defects within the protective film 17, and identify regions of the detected defects. Specifically, if the protective film 17 has any defect 40, there exists a high electrical conductivity or a low electric resistance between two electrode pieces 19A_{P} and 19B_{Q} (P is an integer of 1 to M; Q is an integer of 1 to N) that cross the region of the defect. Thus, when the detector 21 detects such a state based on the measurement results, it can identify the region of the defects by determining that the region where the two electrode pieces 19A_{P} and 19B_{Q} cross each other contains the defect 40 of the protective film 17. After the defect 40 of the protective film 17 is detected, a repair layer 41 is locally formed on the surface of the second conductive layer 18 at least the region of and in the vicinity of the defect, thereby repairing the defect 40.

As described above, according to the third embodiment, it is possible to identify the region of the defect of the protective film 17 as in the foregoing second embodiment. Thus, an area in which the repair layer 41 is to be formed and whether or not the repair is needed can be determined quickly and easily, depending on the regions of and the number of the defects of the protective film 17. Further, it is possible to easily identify the regions of the defects as compared to the second embodiment.

### 4. Fourth Embodiment

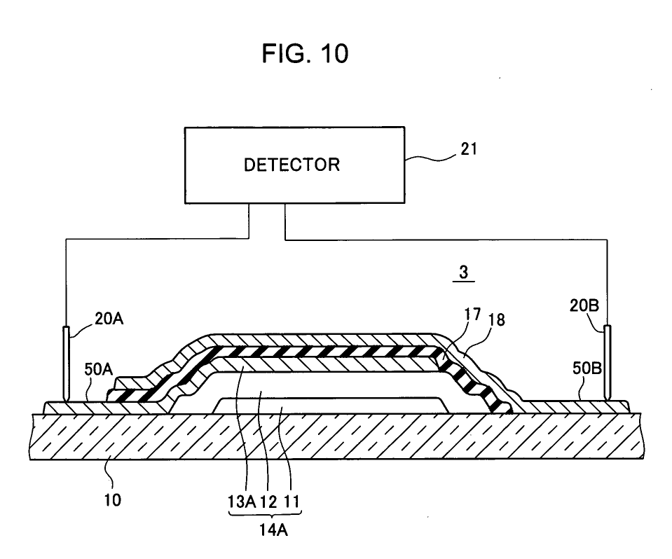

Next, description will be given of a fourth embodiment according to the present invention. FIG. 10 is a diagram schematically showing a cross section of an organic EL panel (semiconductor apparatus) 3 of the fourth embodiment. In FIG. 10, components designated by the same numerals as those shown in FIG. 1 have the same configuration and are manufactured by the same processes as those of the components of the foregoing first embodiment. Detailed description thereof will thus be omitted.

This organic EL panel 3 comprises an insulating substrate 10, and an organic EL device (semiconductor device) 14 consisting of a first electrode layer 11, an organic function layer 12, and a second electrode layer 13A which are formed on this insulating substrate 10. The second electrode layer 13A makes the outermost layer of the organic EL device 14A. The organic EL panel 3 further has a protective film (passivation film) 17 and a conductive layer 18 which are formed in this order on the organic EL device 14.

The protective film 17 is sandwiched between the second electrode layer 13A and the conductive layer 18, and is formed to establish electric insulation between the second electrode layer 13A and the conductive layer 18. The structure of the present embodiment differs from the structure of the foregoing first embodiment in that the second electrode layer 13A of the organic EL device 14A is thus used for defect detection.

As shown in FIG. 10, the second conductive layer 13A exists over a peripheral part of the insulating substrate 10 outside the area in which the organic EL device 14A is formed. The second conductive layer 13A on this peripheral part is continuous with and electrically connected with a first electrode terminal 50A. This electrode terminal 50A has a surface area such that a probe 20A intended for defect detection can make contact with. The conductive layer 18 exists over another peripheral part of the insulating substrate 10 outside the area in which the organic EL device 14A is formed. The conductive layer 18 on this peripheral part is continuous with and electrically connected with a second electrode terminal 50B. This electrode terminal 50B has a surface area such that a probe 20B intended for defect detection can make contact with.

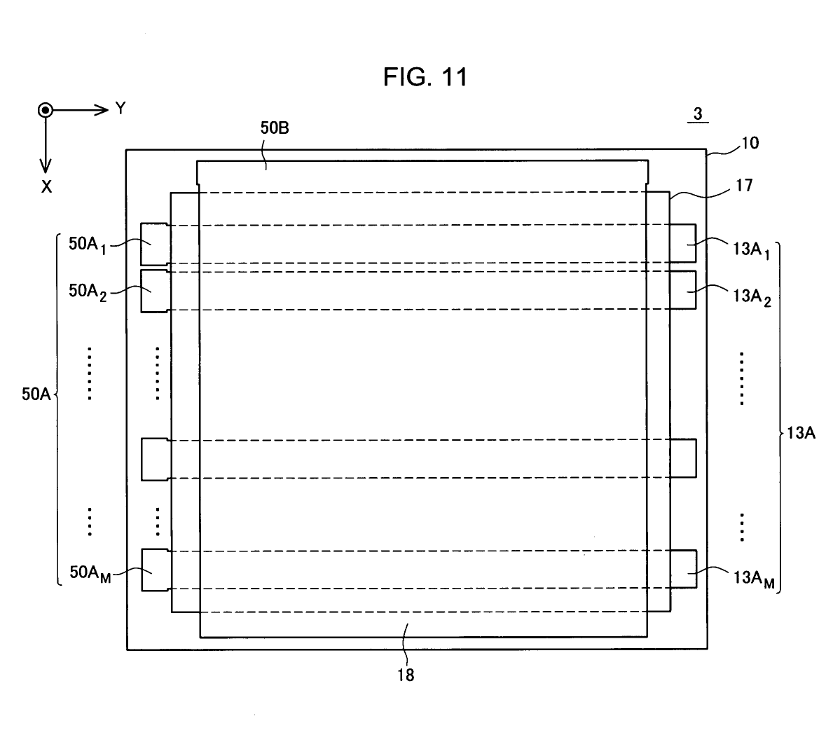

FIG. 11 is a plan view schematically showing the foregoing organic EL panel 3. Referring to FIG. 11, the organic EL device 14A (not shown) is formed in the device-forming area on the insulating substrate 10. The second electrode layer 13A is patterned into stripes along the surface of the insulating substrate 10, thereby forming the band-shaped conductive films 13A₁, 13A₂, . . . , 13A_{M}. These conductive films 13A₁, 13A₂, . . . , 13A_{M} exist over a peripheral part of the insulating substrate 10 into connection with a plurality of electrode pieces 50A₁, 50A₂, . . . , 50A_{M}, respectively. The first electrode terminal 50A is composed of these electrode pieces 50A₁, 50A₂, . . . , 50A_{M}. Moreover, the protective film 17 and the conductive layer 18 are formed in this order on the electrode terminal 50A.

It should be appreciated that in the example shown in FIG. 11, the conductive layer 18 is formed continuously over the entire device-forming area. Alternatively, the conductive layer 18 may be patterned into stripes so as to cross the band-shaped conductive films 13A₁, 13A₂, . . . , 13A_{M}. Moreover, while the second electrode layer 13A shown in FIG. 11 as an example is patterned into stripes, the second electrode layer 13A may be formed continuously over the entire device-forming area.

A method of manufacturing the organic EL panel 3 having the foregoing configuration will now be described schematically.

Referring to FIG. 10, the first electrode layer 11 and the organic function layer 12 are initially formed in this order on the insulating substrate 10. Subsequently, the electrode terminal 50A and the second electrode layer 13A are formed by depositing a conductive material on the organic function layer 12 and by patterning the deposited conductive material. Then, the protective film 17 is formed by depositing an insulating material such as silicon nitride so as to cover the second electrode layer 13A. Furthermore, the conductive layer 18 and the electrode terminal 50B are formed by depositing a metal material such as aluminum to cover this protective film 17 by vapor deposition, sputtering, or the like, followed by patterning.

Then, defect detection processing for measuring and analyzing the electrical conduction between the second electrode layer 13A and the conductive layer 18 is performed. Since the method of this defect detection processing is generally the same as the defect detection methods of the foregoing first to third embodiments, detailed description thereof will be omitted.

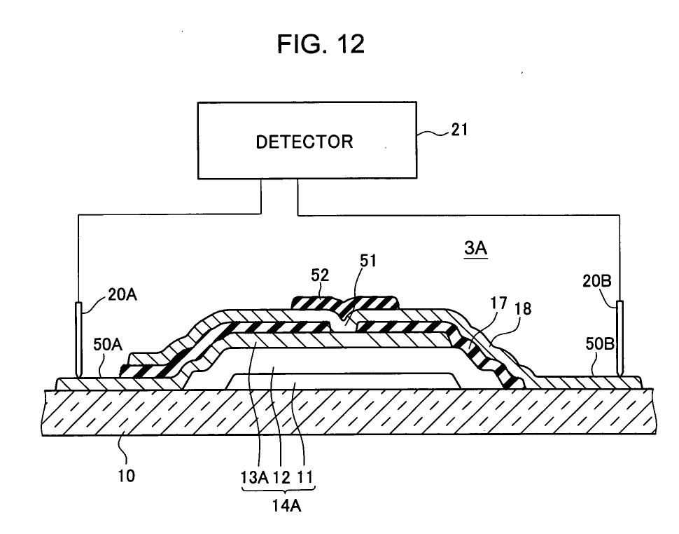

If the protective film 17 has a defect 51 as shown in FIG. 12, the detector 21 detects an abnormality in the electric resistance or the like between the probe 20A in contact with the electrode terminal 50A and the probe 20B in contact with the electrode terminal 50B. In such a case, in the next repair process, a repair layer (patch layer) 52 is formed by depositing an insulating material such as metal nitride on the conductive layer 18 so as to cover the surface of the conductive layer 18 at least the region of and in the vicinity of the detected defect. As a result, it is possible to provide an organic EL panel 3A in which the defect 51 of the protective film 17 is repaired as shown in FIG. 12.

It should be appreciated that after the formation of the repair layer 52 described above, a sealing member for sealing the entire organic EL panel 3A may be formed in order to further improve sealing capability and reinforcement in mechanical strength. Specifically, a metal member with a drying agent may be attached to the insulating substrate 10 as a sealing member by using an ultraviolet-curable resin or other adhesive under an inert gas environment.

As has been described, according to the fourth embodiment, the second electrode layer 13A for constituting the organic EL device 14A is also used to detect defects of the protective film 17. This makes it possible to provide an organic EL panel of high spatial efficiency. The smaller number of manufacturing steps allows suppression of the manufacturing cost.

In the foregoing, the description has been given of the first to fourth embodiments according to the present invention. The sealing structures and manufacturing methods of the foregoing embodiments are not limited to organic EL devices, and may be applied to any semiconductor device that requires a protective film, such as a laser diode and a capacitive device.

1. A semiconductor apparatus comprising a substrate, a semiconductor device formed on said substrate, and a protective film for sealing said semiconductor device, said semiconductor apparatus further comprising:
a first conductive layer in contact with a back surface of said protective film; and
a second conductive layer in contact with a front surface of said protective film.

2. The semiconductor apparatus according to claim 1, further comprising an insulating film of electrical insulation formed on said semiconductor device, said first conductive layer being formed on said insulating film.

3. The semiconductor apparatus according to claim 1, wherein said semiconductor device includes an outermost electrode layer as said first conductive layer.

4. The semiconductor apparatus according to claim 1, wherein at least one of said first conductive layer and said second conductive layer is patterned into stripes.

5. The semiconductor apparatus according to claim 1, wherein said first conductive layer and said second conductive layer are patterned into stripes so as to cross each other.

6. The semiconductor apparatus according to claim 1, further comprising:
a first electrode terminal in connection with said first conductive layer; and
a second electrode terminal in connection with said second conductive layer.

7. The semiconductor apparatus according to claim 6, wherein said first and second electrode terminals are formed on a peripheral part of said substrate, said peripheral part being located outside an area in which said semiconductor device is formed.

8. The semiconductor apparatus according to claim 6, wherein at least either one of said first electrode terminal and said second electrode terminal is made of a plurality of electrode pieces arranged at predetermined intervals along a peripheral part of said substrate.

9. The semiconductor apparatus according to claim 1, wherein said semiconductor device includes an electroluminescent device.

10. A method of manufacturing a semiconductor apparatus for detecting a defect within a protective film which seals a semiconductor device formed on a substrate, said method comprising the steps of:
(a) forming a first conductive layer;
(b) forming a protective film for covering said semiconductor device on said first conductive layer;
(c) forming a second conductive layer on said protective film; and
(d) measuring electrical conduction between said first conductive layer and said second conductive layer, and detecting a defect within said protective film based on the measurement result.

11. The method of manufacturing a semiconductor apparatus according to claim 10, further comprising the step of, after a defect of said protective film is detected in said step (d), forming a repair layer for covering a surface of said second conductive layer corresponding to at least a region of and in the vicinity of the detected defect of said protective film.

12. The method of manufacturing a semiconductor apparatus according to claim 10, further comprising the step of forming an insulating film of electrical insulation on said semiconductor device, and wherein said first conductive layer is formed on said insulating film in said step (a).

13. The method of manufacturing a semiconductor apparatus according to claim 10, wherein said semiconductor device includes an outermost electrode layer as said first conductive layer.

14. The method of manufacturing a semiconductor apparatus according to claim 10, wherein said first conductive layer is patterned in stripes in said step (a).

15. The method of manufacturing a semiconductor apparatus according to claim 10, wherein said second conductive layer is formed in stripes in said step (c).

16. The method of manufacturing a semiconductor apparatus according to claim 10, wherein said steps (a) and (c) include patterning said first conductive layer and said second conductive layer in stripes so as to cross each other.

17. The method of manufacturing a semiconductor apparatus according to claim 10, wherein: said step (a) includes forming a first electrode terminal in connection with said first conductive layer; and said step (c) includes forming a second electrode terminal in connection with said second conductive layer.

18. The method of manufacturing a semiconductor apparatus according to claim 17, wherein said step (d) includes:
measuring electrical conduction between first and second probes, said first probe being in contact with a surface of either one of said first electrode terminal and said second electrode terminal, while scanning said second probe in contact with and across a surface of the other of said first electrode terminal and said second electrode terminal; and
identifying a region of the defect of said protective film based on the measurement result.

19. The method of manufacturing a semiconductor apparatus according to claim 17, wherein said step (d) includes:
measuring electrical conduction between first and second probes, said first probe being into contact with a surface of either one of said first electrode terminal and said second electrode terminal, while sequentially connecting said second probe to a plurality of predetermined points on a surface of the other of said first electrode terminal and said second electrode terminal; and
identifying a region of the defect: of said protective film based on the measurement results.

20. The method of manufacturing a semiconductor apparatus according to claim 17, wherein, in each of said steps (a) and (c), said first and second electrode terminals are formed on a peripheral part of said substrate, said peripheral part being located outside an area in which said semiconductor device is formed.

21. The method of manufacturing a semiconductor apparatus according to claim 17, wherein said step (a) includes forming a plurality of electrode pieces as said first electrode terminal, said electrode pieces being arranged at predetermined intervals along a peripheral part of said substrate.

22. The method of manufacturing a semiconductor apparatus according to claim 17, wherein said step (c) includes forming a plurality of electrode pieces as said second electrode terminal, said electrode pieces being arranged at predetermined intervals along a peripheral part of said substrate.

23. The method of manufacturing a semiconductor apparatus according to claim 10, wherein said semiconductor device includes an electroluminescent device.
